(19) United States
(12) Patent Application Publication
(10) Pub. No.: US 2025/0029897 A1
(43) Pub. Date: Jan. 23, 2025

(54) SEMICONDUCTOR DEVICE

(71) Applicant: SAMSUNG ELECTRONICS CO., LTD., Suwon-si (KR)

(72) Inventors: Jun Ki PARK, Suwon-si (KR); Sung Hwan KIM, Suwon-si (KR); Wan Don KIM, Suwon-si (KR); Won Keun CHUNG, Suwon-si (KR)

(73) Assignee: SAMSUNG ELECTRONICS CO., LTD., Suwon-si (KR)

(21) Appl. No.: 18/634,372

(22) Filed: Apr. 12, 2024

(30) Foreign Application Priority Data
Jul. 19, 2023 (KR) 10-2023-0093567

(51) Int. Cl. H01L 23/485; H01L 29/06; H01L 29/08; H01L 29/423; H01L 29/66; H01L 29/775; H01L 29/786

(52) U.S. Cl. CPC H01L 23/485; H01L 29/0665; H01L 29/0847; H01L 29/42392; H01L 29/66439; H01L 29/775; H01L 29/78696

(57) ABSTRACT

A semiconductor device includes a back interlayer insulating film, a back wiring line in the back interlayer insulating film, the back wiring line including a first surface and a second surface opposite the first surface in a first direction, a fin-type pattern on the first surface of the back wiring line and extending in a second direction, a gate electrode on the fin-type pattern and extending in a third direction, a first source/drain pattern on a first side of the gate electrode, the first source/drain pattern including a bottom surface contacting the fin-type pattern, a back source/drain contact in the fin-type pattern and connected to the first surface of the back wiring line, and a contact insulating liner between the fin-type pattern and the back source/drain contact, the contact insulating liner extending along at least a portion of side walls of the back source/drain contact.

### CROSS-REFERENCE TO RELATED APPLICATION(S)

This application is based on and claims priority to Korean Patent Application No. 10-2023-0093567, filed on Jul. 19, 2023, in the Korean Intellectual Property Office, the disclosure of which is incorporated herein by reference in its entirety.

### BACKGROUND

### 1. Field

Example embodiments of the disclosure relate to a semiconductor device.

### 2. Description of Related Art

A multi gate transistor in which a multi-channel active pattern (or a silicon body) having a fin or nanowire shape is formed on a substrate and a gate is formed on a surface of the multi-channel active pattern has been proposed as a scaling technology for increasing density of a semiconductor device.

Since such a multi gate transistor utilizes a three-dimensional channel, scaling is easily performed. Further, even if a gate length of the multi gate transistor is not increased, the current control capability may be improved. Furthermore, a short channel effect (SCE), in which potential of a channel region is influenced by a drain voltage, may be effectively suppressed.

On the other hand, as a pitch size of the semiconductor device decreases, there is a need to reduce the capacitance between contacts in the semiconductor device and ensure electrical stability.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved element performance and reliability.

Additional aspects will be set forth in part in the description which follows and, in part, will be apparent from the description, or may be learned by practice of the presented embodiments.

According to an aspect of an example embodiment, a semiconductor device may include a back interlayer insulating film, a back wiring line in the back interlayer insulating film, the back wiring line including a first surface and a second surface opposite the first surface in a first direction, a fin-type pattern on the first surface of the back wiring line and extending in a second direction, a gate electrode on the fin-type pattern and extending in a third direction, a first source/drain pattern on a first side of the gate electrode, the first source/drain pattern including a bottom surface contacting the fin-type pattern, a back source/drain contact in the fin-type pattern and connected to the first surface of the back wiring line, a contact insulating liner between the fin-type pattern and the back source/drain contact, the contact insulating liner extending along at least a portion of side walls of the back source/drain contact, a first front source/drain contact directly connected to the back source/drain contact, and a first contact silicide film between the first front source/drain contact and the first source/drain pattern.

According to an aspect of an example embodiment, a semiconductor device may include a back interlayer insulating film, a back wiring line in the back interlayer insulating film, and the back wiring line including a first surface and a second surface opposite the first surface in a first direction, a fin-type pattern on the first surface of the back wiring line, and extending in a second direction, a first source/drain pattern and a second source/drain pattern on the fin-type pattern and spaced apart in the second direction, a gate electrode between the first source/drain pattern and the second source/drain pattern, a back source/drain contact in the fin-type pattern and connected to the first surface of the back wiring line, a first front source/drain contact directly connected to the back source/drain contact, the first front source/drain contact including at least a portion in the first source/drain pattern, a second front source/drain contact connected to the second source/drain pattern, the second front source/drain contact including at least a portion in the second source/drain pattern, a first contact silicide film between the first front source/drain contact and the first source/drain pattern, and a second contact silicide film extending along side walls of the second front source/drain contact, where the second contact silicide film does not extend along a bottom surface of the second front source/drain contact.

According to an aspect of an example embodiment, a semiconductor device may include a back interlayer insulating film, a back wiring line in the back interlayer insulating film, the back wiring line including a first surface and a second surface opposite the first surface in a first direction, a fin-type pattern on the first surface of the back wiring line, and extending in a second direction, a plurality of sheet patterns on the fin-type pattern, and spaced apart from the fin-type pattern in the first direction, a gate electrode on the fin-type pattern, extending in a third direction, and at least partially at least partially surrounding the plurality of sheet patterns, a source/drain pattern on a side surface of the gate electrode, the source/drain pattern including a bottom surface contacting the fin-type pattern, a back source/drain contact in the fin-type pattern and connected to the first surface of the back wiring line, a contact insulating liner between the fin-type pattern and the back source/drain contact, the contact insulating liner extending along at least a portion of a side wall of the back source/drain contact, a front source/drain contact directly connected to the back source/drain contact, the front source/drain contact including a least a portion in the source/drain pattern, and a contact silicide film extending along a side wall of the front source/drain contact, where the contact silicide film does not extend along a bottom surface of the front source/drain contact.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a layout diagram illustrating the semiconductor device according to some embodiments;

FIG. 2 is a cross-sectional view taken along line A-A of FIG. 1 according to some embodiments;

FIG. 3 is a cross-sectional view taken along B-B of FIG. 1 according to some embodiments;

FIGS. 4A and 4B are cross-sectional views taken along C-C and D-D of FIG. 1, respectively, according to some embodiments;

FIG. 5 is an enlarged view of a portion P of FIG. 2 according to some embodiments;

FIG. 6 is an enlarged view of a portion Q of FIG. 4A according to some embodiments;

FIGS. 7 and 8 are diagrams illustrating a semiconductor device according to some embodiments;

FIGS. 9 to 11 are diagrams illustrating a semiconductor device according to some embodiments;

FIG. 12 is a diagram illustrating a semiconductor device according to some embodiments;

FIGS. 13 and 14 are diagrams illustrating a semiconductor device according to some embodiments;

FIG. 15 is a diagram illustrating a semiconductor device according to some embodiments;

FIGS. 16 and 17 are diagrams illustrating a semiconductor device according to some embodiments;

FIGS. 18 to 20B are diagrams illustrating a semiconductor device according to some embodiments; and

FIGS. 21 to 29 are diagrams illustrating a method for fabricating a semiconductor device according to some embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms. Although terms such as first and second are used to describe various elements or components in the present specification, these elements or components are not limited by these terms. These terms are only used to distinguish a single element or component from other elements or components. Therefore, a first element or component may be a second element or component, and so forth.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Although drawings relating to a semiconductor device according to some embodiments show, as an example, a transistor including a nanowire or a nanosheet, and a Multi-Bridge Channel field effect transistor (FET) (MBCFET™), embodiments are not limited thereto and the semiconductor device according to some embodiments may also be applied to a fin-type transistor (FinFET) including a fin-type pattern-shaped channel region.

The semiconductor device according to some embodiments may include a tunneling transistor (tunneling FET), a three-dimensional (3D) transistor or a vertical transistor (Vertical FET). The semiconductor device according to some embodiments may include a planar transistor. In addition, embodiments may be applied to a transistor based on two-dimensional (2D) material based FETs and a heterostructure thereof.

Further, the semiconductor device according to some embodiments may also include a bipolar junction transistor, a laterally diffused metal oxide semiconductor (LDMOS), or the like.

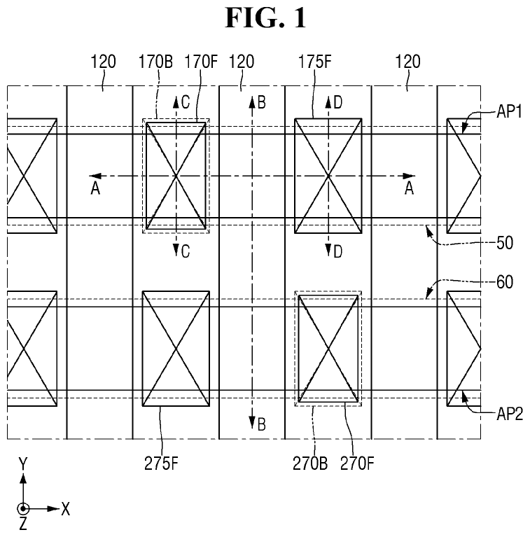

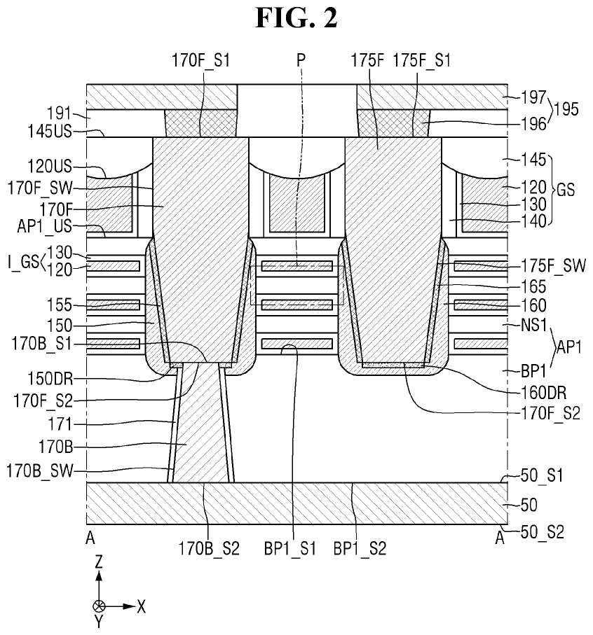

The semiconductor devices according to some embodiments will be described with reference to FIGS. 1 to 6.

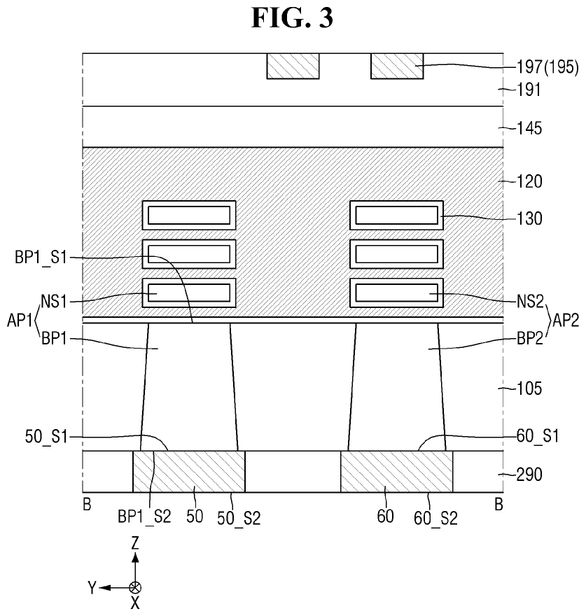

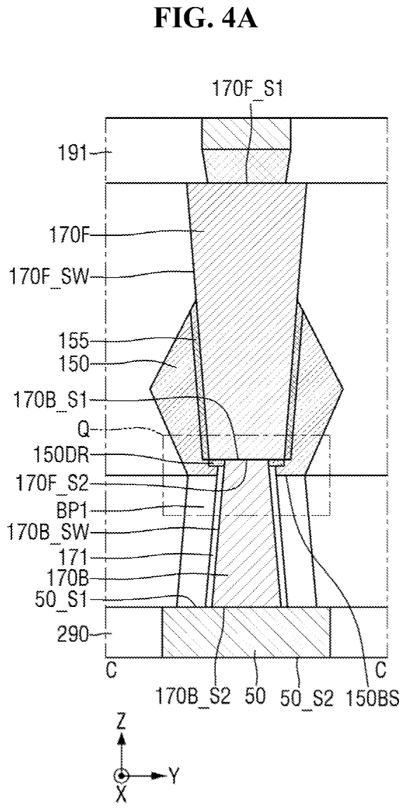

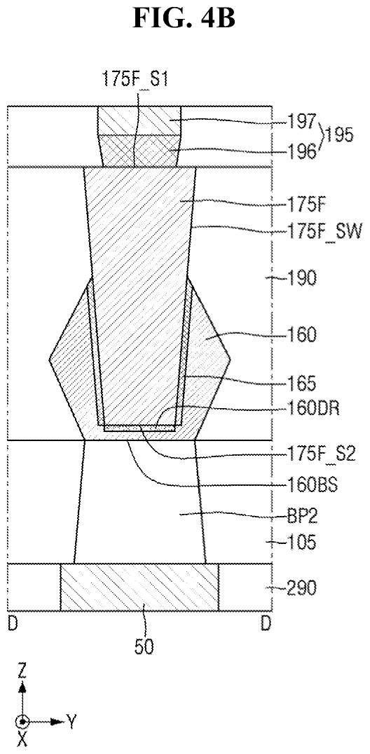

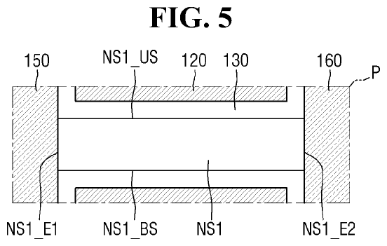

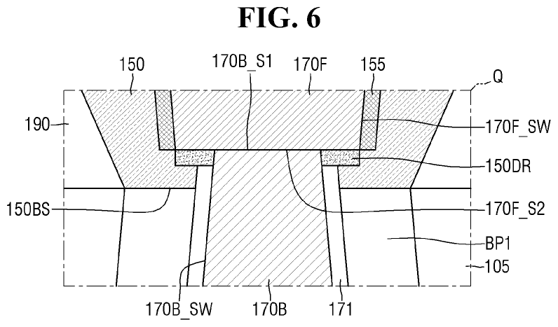

FIG. 1 is a layout diagram illustrating the semiconductor device according to some embodiments. FIG. 2 is a cross-sectional view taken along line A-A of FIG. 1 according to some embodiments. FIG. 3 is a cross-sectional view taken along B-B of FIG. 1 according to some embodiments. FIGS. 4A and 4B are cross-sectional views taken along C-C and D-D of FIG. 1, respectively, according to some embodiments. FIG. 5 is an enlarged view of a portion P of FIG. 2 according to some embodiments. FIG. 6 is an enlarged view of a portion Q of FIG. 4A according to some embodiments. For convenience of explanation, a front wiring structure 195 is not shown in FIG. 1.

Although FIG. 2 depicts a cross-sectional view taken along line A-A of FIG. 1, which extends across a first active pattern AP1, a cross-sectional view taken in the first direction X along a second active pattern AP2 may be similar to FIG. 2.

Referring to FIGS. 1 to 6, the semiconductor device according to some embodiments may include a first active pattern AP1, a second active pattern AP2, a plurality of gate electrodes 120, a first source/drain pattern 150, a second source/drain pattern 160, a first front source/drain contact 170F, a second front source/drain contact 270F, a third front source/drain contact 175F, a fourth front source/drain contact 275F, a first back source/drain contact 170B, a second back source/drain contact 270B, a first back wiring line 50, a second back wiring line 60, and a front wiring structure 195.

The first back wiring line 50 and the second back wiring line 60 may be disposed in a back interlayer insulating film 290. The first back wiring line 50 and the second back wiring line 60 may each extend in a first direction X. The first back wiring lines 50 may be spaced apart from the second back wiring line 60 in a second direction Y.

As an example, the first back wiring line 50 and the second back wiring line 60 may be power lines that supply power to the semiconductor device. As another example, the first back wiring line 50 and the second back wiring line 60 may be signal lines that supply operating signals for the semiconductor device. As still another example, one of the first back wiring line 50 and the second back wiring line 60 may be a power line, and the other may be a signal line.

The first back wiring line 50 may include a first surface 50_S1 and a second surface 50_S2 that are opposite to each other in a third direction Z. The second back wiring line 60 may include a first surface 60_S1 and a second surface 60_S2 that are opposite to each other in the third direction Z. The first direction X may intersect the second direction Y and the third direction Z. Also, the second direction Y may intersect the third direction Z.

Although the first back wiring line 50 and the second back wiring line 60 are shown as having rectangular cross-sections, the embodiment is not limited thereto. The first back wiring line 50 and the second back wiring line 60 may have a trapezoidal cross-section. As an example, a width of the first surface 50_S1 of the first back wiring line 50 in the second direction Y may be smaller than a width of the second surface 50_S2 of the first back wiring line 50 in the second direction Y.

For example, the first back wiring line 50 and the second back wiring line 60 may be formed using a damascene process. After a trench extending in the first direction X is formed inside the back interlayer insulating film 290, the first back wiring line 50 may be formed by filling the trench.

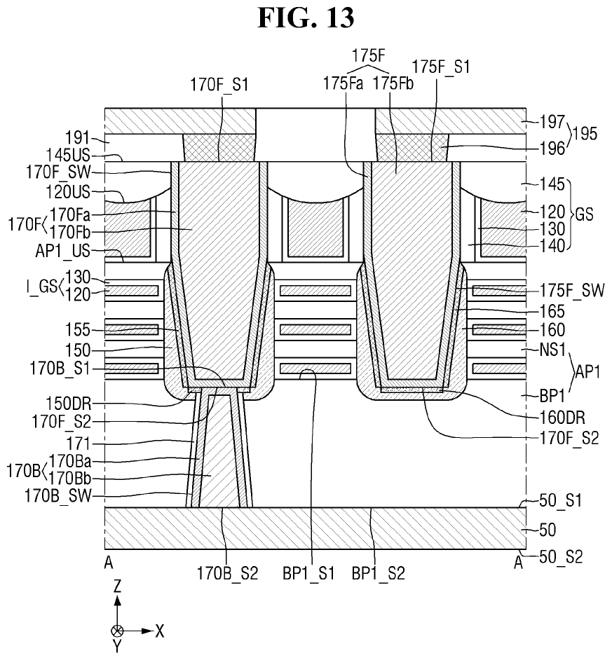

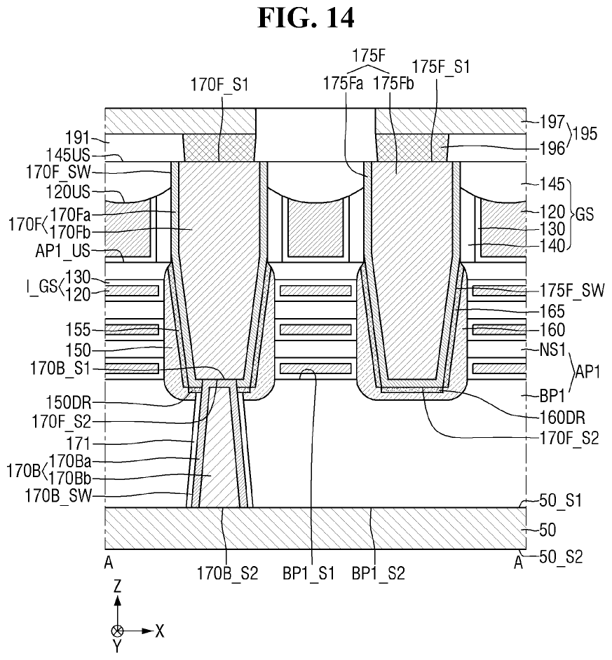

Although the first back wiring line 50 and the second back wiring line 60 are shown as having a single conductive film structure, the embodiment is not limited thereto. The first back wiring line 50 and the second back wiring line 60 may have multiple conductive film structures, such as the source/drain contact 170F and the source/drain contact 175F shown in FIGS. 13 and 14.

The first back wiring line 50 and the second back wiring line 60 may include, for example, at least one of metal, conductive metal nitride, conductive metal carbide, conductive metal oxide, conductive metal carbonitride, and a 2D material. The 2D material may include a 2D allotrope or a 2D compound, and may include, for example, but not limited to, at least one of graphene, boron nitride (BN), molybdenum sulfide, molybdenum selenide, tungsten sulfide, tungsten selenide, and tantalum sulfide. That is, since the above-mentioned 2D materials are only listed by way of example, the 2D materials that may be included in the semiconductor device of the present disclosure are not limited by the above-mentioned materials.

The first back wiring line 50 and the second back wiring line 60 may each extend in the second direction Y. In such cases, the shape of the cross-sectional views taken along A-A, B-B, C-C and D-D of FIG. 1 may vary.

The back interlayer insulating film 290 may include, for example, at least one of silicon oxide, silicon nitride, silicon carbonitride, silicon oxynitride, and a low dielectric constant material. The dielectric constant of the low dielectric constant material may have a value smaller than 3.9, which is the dielectric constant of silicon oxide.

The first active pattern AP1 and the second active pattern AP2 may each be disposed on the back interlayer insulating film 290. Each of the first active pattern AP1 and the second active pattern AP2 may extend in the first direction X.

For example, each of the first active pattern AP1 and the second active pattern AP2 may be disposed on the first back wiring line 50 and the second back wiring line 60. Each of the first active pattern AP1 and the second active pattern AP2 may be disposed on the first surface 50_S1 of the first back wiring line 50 and the first surface 60_S1 of the second back wiring line 60. The first surface 50_S1 of the first back wiring line and the first surface 60_S1 of the second back wiring line may face the first active pattern AP1 and the second active pattern AP2.

The first active pattern AP1 and the second active pattern AP2 may be spaced apart in the second direction Y. The first active pattern AP1 and the second active pattern AP2 may be adjacent in the second direction Y.

Although the first active pattern AP1 is shown as being closest to the second active pattern AP2 in the second direction Y, the embodiment is not limited thereto. An additional active pattern may be disposed between the first active pattern AP1 and the second active pattern AP2.

As an example, the first active pattern AP1 may be a region in which a p-type transistor is formed, and the second active pattern AP2 may be a region in which an n-type transistor is formed. As another example, the first active pattern AP1 and the second active pattern AP2 may be regions in which the p-type transistor is formed. As yet another example, the first active pattern AP1 and the second active pattern AP2 may be regions in which the n-type transistor is formed. Hereinafter, it will be described that the first active pattern AP1 and the second active pattern AP2 are regions in which transistors of different conductive types are formed.

The first active pattern AP1 and the second active pattern AP2 may each be multi-channel active patterns. For example, the first active pattern AP1 may include a first lower pattern BP1 and a plurality of first sheet patterns NS1. The second active pattern AP2 may include a second lower pattern BP2 and a plurality of second sheet patterns NS2. In the semiconductor device according to some embodiments, the first and second active patterns AP1 and AP2 may each be active patterns including nanosheet or nanowire.

The first lower pattern BP1 and the second lower pattern BP2 may be disposed on the back interlayer insulating film 290. The first lower pattern BP1 and the second lower pattern BP2 may protrude in the third direction Z. Each of the first lower pattern BP1 and the second lower pattern BP2 may be a fin-type pattern.

The first lower pattern BP1 and the second lower pattern BP2 may each extend in the first direction X. The first lower pattern BP1 may be spaced apart from the second lower pattern BP2 in the second direction Y. The first lower pattern BP1 and the second lower pattern BP2 may be separated by a fin trench extending in the first direction X.

The first lower pattern BP1 may include a first surface BP1_S1 and a second surface BP1_S2 that are opposite to each other in the third direction Z. The second surface BP1_S2 of the first lower pattern BP1 may face the back interlayer insulating film 290, the first back wiring line 50, and the second back wiring line 60. The first back wiring line 50 and the second back wiring line 60 may be disposed on the second surface BP1_S2 of the first lower pattern BP1.

For example, the second surface BP1_S2 of the first lower pattern BP1 may be the lower surface of the first lower pattern BP1. The first surface BP1_S1 of the first lower pattern BP1 may be the upper surface of the first lower pattern BP1.

Similar to the first lower pattern BP1, the second lower pattern BP2 may also include a first surface and a second surface that are opposite to each other in the third direction Z. The second surface of the second lower pattern BP2 may face the back interlayer insulating film 290, the first back wiring line 50, and the second back wiring line 60.

The first lower pattern BP1 may include side walls that connect the first surface BP1_S1 of the first lower pattern BP1 and the second surface BP1_S2 of the first lower pattern BP1. The side wall of the first lower pattern BP1 may extend in the first direction X. The second lower pattern BP2 may include side walls extending in the first direction X. The side walls of the second lower pattern BP2 surface the side walls of the first lower pattern BP1.

The plurality of first sheet patterns NS1 may be disposed on the first lower pattern BP1. The plurality of first sheet patterns NS1 may be disposed on the first surface BP1_S1 of the first lower pattern BP1. The plurality of first sheet patterns NS1 may be spaced apart from the first lower patterns BP1 in the third direction Z.

The plurality of second sheet patterns NS2 may be disposed on the second lower pattern BP2. The plurality of second sheet patterns NS2 may be disposed on the upper surface of the second lower pattern BP2. The plurality of second sheet patterns NS2 may be spaced apart from the second lower patterns BP2 in the third direction Z.

The first sheet pattern NS1 and the second sheet pattern NS2 may be disposed on the first surface 50_S1 of the first back wiring line 50 and the first surface 60_S1 of the second back wiring line 60.

Although each of three first sheet patterns NS1 and three second sheet patterns NS2 is shown as being disposed in the third direction Z, this is only for convenience of explanation, and the embodiment is not limited thereto.

In FIGS. 2 and 5, the first sheet pattern NS1 may include an upper surface NS1_US and a lower surface NS1_BS. The upper surface NS1_US of the first sheet pattern NS1 may be opposite to the lower surface NS1_BS of the first sheet pattern NS1 in the third direction Z. The lower surface NS1_BS of the first sheet pattern NS1 may face the first back wiring line 50 and the second back wiring line 60.

The first sheet pattern NS1 may include a first end NS1_E1 and a second end NS1_E2. The first end NS1_E1 of the first sheet pattern NS1 is spaced apart from the second end NS1_E2 of the first sheet pattern NS1 in the first direction X. The first end NS1_E1 of the first sheet pattern NS1 and the second end NS1_E2 of the first sheet pattern NS1 may be portions connected to source/drain patterns 150 and 160 which will be described later.

The first sheet pattern NS1 may include an uppermost sheet pattern that is farthest from the first back wiring line 50 and the second back wiring line 60. The upper surface AP1_US of the first active pattern AP1 may be the upper surface of the uppermost sheet pattern among the first sheet patterns NS1. The second active pattern AP2 and the second sheet pattern NS2 may be substantially the same as the first active pattern AP1 and the first sheet pattern NS1, and thus repeated descriptions may be omitted.

The first lower pattern BP1 and the second lower pattern BP2 may each include, for example, silicon or germanium, which are elemental semiconductor materials. Further, the first lower pattern BP1 and the second lower pattern BP2 may each include a compound semiconductor, and may include, for example, a group IV-IV compound semiconductor or a group III-V compound semiconductor.

The group IV-IV compound semiconductor may include, for example, a binary compound or a ternary compound including at least two or more of carbon (C), silicon (Si), germanium (Ge) and tin (Sn), or a compound obtained by doping these elements with a group IV element.

The group III-V compound semiconductor may be, for example, at least one of a binary compound, a ternary compound or a quaternary compound formed by combining at least one of aluminum (Al), gallium (Ga) and indium (In) as a group III element with one of phosphorus (P), arsenic (As) and antimony (Sb) as a group V element.

Each of the first sheet pattern NS1 and the second sheet pattern NS2 may include one of silicon or germanium which are elemental semiconductor materials, a group IV-IV compound semiconductor or a group III-V compound semiconductor. A width of the first sheet pattern NS1 in the second direction Y may increase or decrease in proportion to a width of the first lower pattern BP1 in the second direction Y. The width of the second sheet pattern NS2 in the second direction Y may increase or decrease in proportion to the width of the second lower pattern BP2 in the second direction Y.

Although the width of each first sheet pattern NS1 disposed on the first lower pattern BP1 in the second direction Y is shown as being the same, the embodiment is not limited thereto.

The field insulating film 105 may be disposed on the first back wiring line 50 and the second back wiring line 60. For example, the field insulating film 105 may be disposed on the first surface 50_S1 of the first back wiring line 50 and the first surface 60_S1 of the second back wiring line 60.

The field insulating film 105 may be disposed on side walls of the first lower pattern BP1 and side walls of the second lower pattern BP2. For example, the field insulating film 105 may cover the side walls of the first lower pattern BP1 and the side walls of the second lower pattern BP2. As another example, the field insulating film 105 may partially cover the side walls of the first lower pattern BP1 and/or the side walls of the second lower pattern BP2.

In some embodiments, the field insulating film 105 may not cover the first surface BP1_S1 of the first lower pattern BP1 and the upper surface of the second lower pattern BP2. The first sheet pattern NS1 and the second sheet pattern NS2 may be disposed to be higher than the upper surface of the field insulating film 105. The field insulating film 105 may include an upper surface and a lower surface that are opposite to each other in the third direction Z. The lower surface of the field insulating film 105 may face the first back wiring line 50 and the second back wiring line 60.

The field insulating film 105 may include, for example, an oxide film, a nitride film, an oxynitride film or a combined film thereof. Although the field insulating film 105 is shown as a single film, it is only for convenience of explanation, and the embodiment is not limited thereto.

Although the first lower pattern BP1 is shown as contacting the first back wiring line 50 and the second lower pattern BP2 is shown as contacting the second back wiring line 60, the embodiment is not limited thereto. In some embodiment, with the first lower pattern BP1 as an example, an insulating film may be inserted between the second surface BP1_S2 of the first lower pattern BP1 and the first surface 50_S1 of the first back wiring line 50.

A plurality of gate structures GS may be disposed on the upper surface of the field insulating film 105. Each gate structure GS may extend in the second direction Y. The gate structures GS may be spaced apart in the first direction X. The gate structures GS may be adjacent to each other in the first direction X. For convenience of description, the plurality of gate structures GS may be referred to as a singular gate structure GS.

The gate structure GS may be disposed on the first active pattern AP1 and the second active pattern AP2. The gate structure GS may intersect the first active pattern AP1 and the second active pattern AP.

The gate structure GS may intersect the first lower pattern BP1 and the second lower pattern BP2. The gate structure GS may surround or at least partially surround each first sheet pattern NS1. The gate structure GS may surround or at least partially surround each second sheet pattern NS2.

Although the gate structure GS is shown as being disposed over the first active pattern AP1 and the second active pattern AP2, it is only for convenience of explanation, and the embodiment is not limited thereto. That is, a portion of the gate structure GS may be divided into two portions by a gate isolation structure disposed on the field insulating film 105 and disposed on the first active pattern AP1 and the second active pattern AP2.

The gate structure GS1 may include, for example, a gate electrode 120, a gate insulating film 130, a gate spacer 140, and a gate capping pattern 145.

The gate structure GS may include a plurality of inner gate structures I_GS disposed between the first sheet patterns NS1 that are adjacent in the third direction Z, and between the first lower pattern BP1 and the first sheet pattern NS1. The inner gate structure I_GS may be disposed between the first surface BP1_S1 of the first lower pattern BP1 and the lower surface NS1_BS of the first sheet pattern NS1, and between the upper surface NS1_US of the first sheet pattern NS1 and the lower surface NS1_BS of the first sheet pattern NS1 that face each other in the third direction Z.

The number of inner gate structures I_GS may be the same as the number of first sheet patterns NS1. The inner gate structure I_GS may contact the first surface BP1_S1 of the first lower pattern BP1, the upper surface NS1_US of the first sheet pattern NS1, and the lower surface NS1_BS of the first sheet pattern NS1. In the semiconductor device according to some embodiments, the inner gate structure I_GS may contact the source/drain patterns 150 and 160, which will be described below.

The inner gate structure I_GS may include a gate electrode 120 and a gate insulating film 130 disposed between adjacent first sheet patterns NS1, and between the first lower pattern BP1 and the first sheet pattern NS1.

The inner gate structure I_GS may be disposed between the second sheet patterns NS2 adjacent in the third direction Z, and between the second lower pattern BP2 and the second sheet pattern NS2.

The gate electrode 120 may be disposed on the first lower pattern BP1 and the second lower pattern BP2. The gate electrode 120 may intersect the first lower pattern BP1 and the second lower pattern BP2. The gate electrode 120 may surround or at least partially surround the first sheet pattern NS1 and the second sheet pattern NS2.

Although the upper surface 120 US of the gate electrode 120 is shown to be a concave curved surface in a cross-sectional view such as FIG. 2, the embodiment is not limited thereto. The upper surface 120US of the gate electrode 120 may be a plane.

The gate electrode 120 may include at least one of metal, conductive metal nitride, metal silicide, doped semiconductor material, conductive metal oxide and conductive metal oxynitride. The gate electrode 120 may include, but is not limited to, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof. The conductive metal oxide and conductive metal oxynitride may include, but are not limited to, an oxidized form of the aforementioned materials.

The gate insulating film 130 may extend along the upper surface of the field insulating film 105, the first surface BP1_S1 of the first lower pattern BP1, and the upper surface of the second lower pattern BP2. The gate insulating film 130 may surround or at least partially surround the plurality of first sheet patterns NS1. The gate insulating film 130 may surround or at least partially surround the plurality of second sheet patterns NS2. The gate insulating film 130 may be disposed along the periphery of the first sheet pattern NS1 and the periphery of the second sheet pattern NS2. The gate electrode 120 is disposed on the gate insulating film 130.

The gate insulating film 130 may be disposed between the gate electrode 120 and the first sheet pattern NS1, and between the gate electrode 120 and the second sheet pattern NS2. In the semiconductor device according to some embodiments, the gate insulating film 130 included in the inner gate structure I_GS may contact the source/drain patterns 150 and 160, which will be described later.

The gate insulating film 130 may include silicon oxide, silicon oxynitride, silicon nitride or a high dielectric constant material having a higher dielectric constant than silicon oxide. The high dielectric constant material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

Although the gate insulating film 130 is shown as a single film, this example is only for convenience of explanation and is not limited thereto. The gate insulating film 130 may include a plurality of films. The gate insulating film 130 may include an interfacial layer and a high dielectric constant insulating film disposed between the first active pattern AP1 and the gate electrode 120, and between the second active pattern AP2 and the gate electrode 120. For example, the interfacial layer may not be formed along the profile of the upper surface of the field insulating film 105.

The semiconductor device according to some embodiments may include a negative capacitance (NC) FET that uses a negative capacitor. For example, the gate insulating film 130 may include a ferroelectric material film having ferroelectric properties, and a paraelectric material film having paraelectric properties.

The ferroelectric material film may have a negative capacitance, and the paraelectric material film may have a positive capacitance. For example, if two or more capacitors are connected in series and the capacitance of each capacitor has a positive value, the overall capacitances decrease from the capacitance of each of the individual capacitors. On the other hand, if at least one of the capacitances of two or more capacitors connected in series has a negative value, the overall capacitances may be greater than an absolute value of each of the individual capacitances, while having a positive value.

When the ferroelectric material film having the negative capacitance and the paraelectric material film having the positive capacitance are connected in series, the overall capacitance values of the ferroelectric material film and the paraelectric material film connected in series may increase. By the use of the increased overall capacitance value, a transistor including the ferroelectric material film may have a subthreshold swing (SS) below 60 mV/decade at room temperature.

The ferroelectric material film may have ferroelectric properties. The ferroelectric material film may include, for example, at least one of hafnium oxide, hafnium zirconium oxide, barium strontium titanium oxide, barium titanium oxide, and lead zirconium titanium oxide. As an example, the hafnium zirconium oxide may be a material obtained by doping hafnium oxide with zirconium (Zr). As another example, the hafnium zirconium oxide may be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % (at %) aluminum. A ratio of the dopant may be a ratio of aluminum to the sum of hafnium and aluminum.

When the dopant is silicon (Si), the ferroelectric material film may include 2 to 10 at % silicon. When the dopant is yttrium (Y), the ferroelectric material film may include 2 to 10 at % yttrium. When the dopant is gadolinium (Gd), the ferroelectric material film may include 1 to 7 at % gadolinium. When the dopant is zirconium (Zr), the ferroelectric material film may include 50 to 80 at % zirconium.

The paraelectric material film may have the paraelectric properties. The paraelectric material film may include at least one of, for example, a silicon oxide and a metal oxide having a high dielectric constant. The metal oxide included in the paraelectric material film may include, for example, but is not limited to, at least one of hafnium oxide, zirconium oxide, and aluminum oxide.

The ferroelectric material film and the paraelectric material film may include the same material. The ferroelectric material film has the ferroelectric properties, but the paraelectric material film may not have the ferroelectric properties. For example, when the ferroelectric material film and the paraelectric material film include hafnium oxide, a crystal structure of hafnium oxide included in the ferroelectric material film is different from a crystal structure of hafnium oxide included in the paraelectric material film.

The ferroelectric material film may have a thickness having the ferroelectric properties. The thickness of the ferroelectric material film may be, for example, but is not limited to, about 0.5 to about 10 nm. Since a critical thickness that exhibits the ferroelectric properties may vary for each ferroelectric material, the thickness of the ferroelectric material film may vary depending on the ferroelectric material.

As an example, the gate insulating film 130 may include one ferroelectric material film. As another example, the gate insulating film 130 may include a plurality of ferroelectric material films spaced apart from each other. The gate insulating film 130 may have a stacked film structure in which the plurality of ferroelectric material films and the plurality of paraelectric material films are alternately stacked.

The gate spacer 140 may be disposed on the side wall of the gate electrode 120. The gate spacer 140 may not be disposed between the lower patterns (e.g., lower pattern BP1, etc.) and the sheet patterns (e.g., sheet pattern NS1, etc.), and between the sheet patterns (e.g., sheet patterns NS1, NS2, etc.) adjacent in the third direction D3.

The gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and combinations thereof. Although the gate spacers 140 are each shown to be a single film, this example is only for convenience of explanation and is not limited thereto.

A gate capping pattern 145 may be disposed on the gate electrode 120. An upper surface 145US of the gate capping pattern 145 may be coplanar with an upper surface of the first interlayer insulating film 190. The gate capping pattern 145 may be disposed between the gate spacers 140, unlike the shown example.

The gate capping pattern 145 may include, for example, at least one of silicon nitride (SiN), silicon oxynitride (SiON), silicon carbonitride (SiCN), silicon oxycarbonitride (SiOCN), and combinations thereof. The gate capping pattern 145 may include a material having an etch selectivity with respect to the first interlayer insulating film 190.

A first source/drain pattern 150 may be disposed on the first active pattern AP1. The first source/drain pattern 150 may be disposed on the first lower pattern BP1. For example, the first source/drain pattern 150 may be disposed on the first surface BP1_S1 of the first lower pattern BP1.

The first source/drain pattern 150 may be disposed between the gate electrodes 120 adjacent in the first direction X. The first source/drain pattern 150 may be disposed on a side surface of the gate electrode 120. The first source/drain pattern 150 may contact the first active pattern AP1. The first source/drain pattern 150 may contact the first sheet pattern NS1. The first source/drain pattern 150 may be disposed on the first surface 50_S1 of the first back wiring line 50 and the first surface 60_S1 of the second back wiring line 60. The first source/drain pattern 150 may be connected to the first end NS1_E1 of the first sheet pattern NS1.

The second source/drain pattern 160 may be disposed on the first active pattern AP1. The second source/drain pattern 160 may be disposed on the first lower pattern BP1. For example, the second source/drain pattern 160 may be disposed on the first surface BP1_S1 of the first lower pattern BP1.

The second source/drain pattern 160 may be disposed between the gate electrodes 120 adjacent in the first direction X. The second source/drain pattern 160 may be disposed on the side surface of the gate electrode 120.

The gate electrode 120 may be disposed between the first source/drain pattern 150 and the second source/drain pattern 160. The first source/drain pattern 150 may be disposed on one side of the gate electrode 120, and the second source/drain pattern 160 may be disposed on the other side of the gate electrode 120.

The second source/drain pattern 160 may contact the first active pattern AP1. The second source/drain pattern 160 may contact the first sheet pattern NS1. The second source/drain pattern 160 may be disposed on the first surface 50_S1 of the first back wiring line 50 and the first surface 60_S1 of the second back wiring line 60. The second source/drain pattern 160 may be connected to the second end NS1_E2 of the first sheet pattern NS1.

The first source/drain pattern 150 and the second source/drain pattern 160 may contact the first lower pattern BP1. A bottom surface 150BS of the first source/drain pattern 150 and a bottom surface 160BS of the second source/drain pattern 160 may contact the first lower pattern BP1.

A source/drain pattern may be disposed on the second lower pattern BP2 between the gate electrodes 120. The source/drain pattern on the second lower pattern BP2 may be connected to the end of the second sheet pattern NS2.

The first source/drain pattern 150 and the second source/drain pattern 160 may be included in a source/drain of a transistor that uses the first sheet pattern NS1 as a channel region.

The first source/drain pattern 150 and the second source/drain pattern 160 may each include an epitaxial pattern. The first source/drain pattern 150 and the second source/drain pattern 160 may each include a semiconductor material.

The first source/drain pattern 150 and the second source/drain pattern 160 may include, for example, silicon or germanium which is an elemental semiconductor material. Also, the first source/drain pattern 150 and the second source/drain pattern 160 may include, for example, a binary compound or a ternary compound including at least two or more of carbon (C), silicon (Si), germanium (Ge), and tin (Sn), or a compound obtained by doping these elements with a group IV element. The first source/drain pattern 150 and the second source/drain pattern 160 may each include an epitaxial film made of semiconductor. Although the first source/drain pattern 150 and the second source/drain pattern 160 are shown as single film, the example is only for convenience of explanation and is not limited thereto.

The first source/drain pattern 150 and the second source/drain pattern 160 may include dopants doped into the semiconductor material. The first source/drain pattern 150 and the second source/drain pattern 160 include dopants of the same conductive type.

As an example, the first source/drain pattern 150 and the second source/drain pattern 160 include, for example, p-type dopant. The p-type dopant may include, but is not limited to, at least one of boron (B) and gallium (Ga).

As another example, the first source/drain pattern 150 and the second source/drain pattern 160 include, for example, n-type dopant. The n-type dopant may include, but is not limited to, at least one of phosphorus (P), arsenic (As), antimony (Sb) and bismuth (Bi).

In FIGS. 4A and 4B, although the form of the first source/drain pattern 150 and the form of the second source/drain pattern 160 is shown to be a shape similar to a hexagon, the embodiment is not limited thereto. The form of the first source/drain pattern 150 and the form of the second source/drain pattern 160 may be a shape similar to a pentagon or a square.

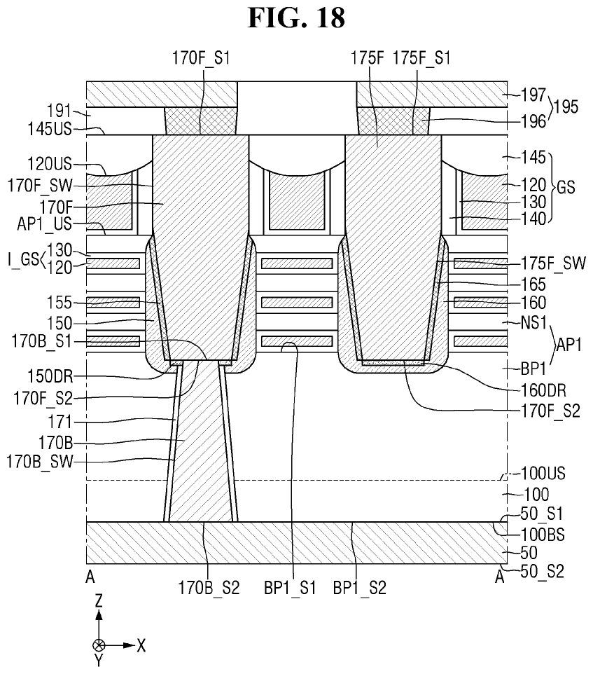

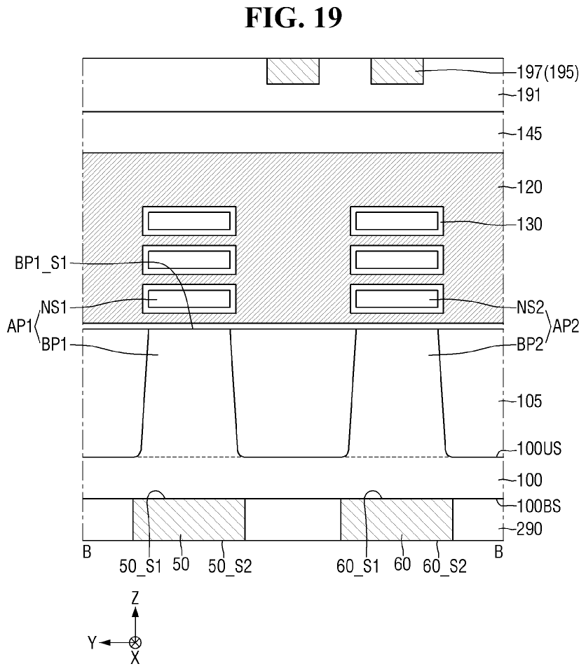

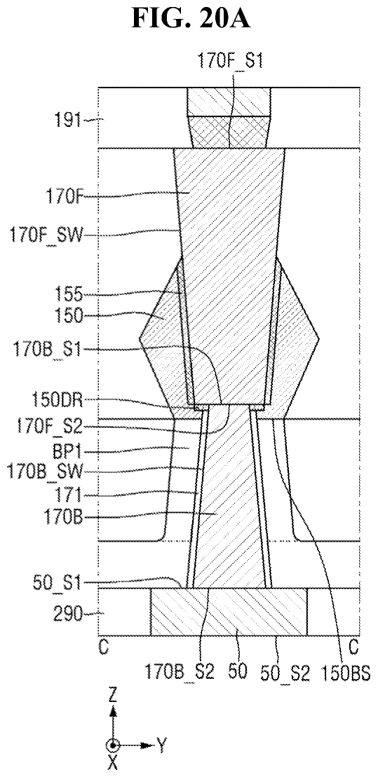

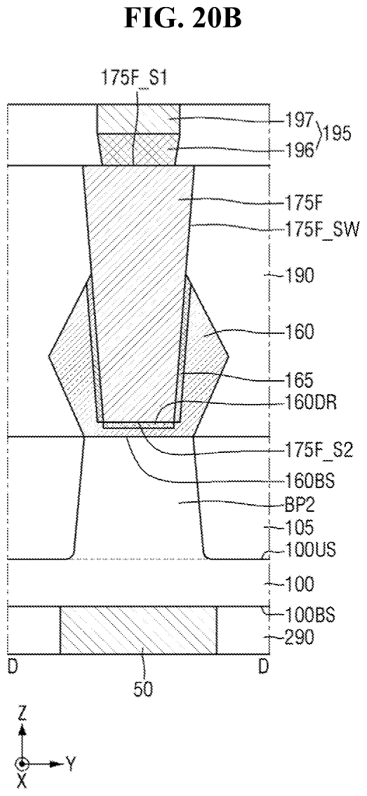

The first interlayer insulating film 190 is disposed on the upper surface 100US of the substrate (e.g., a substrate 100 of FIGS. 18 to 20B). The first interlayer insulating film 190 may be disposed on the first source/drain pattern 150 and the second source/drain pattern 160. The first interlayer insulating film 190 may not cover the upper surface of the gate capping pattern 145. For example, the upper surface of the first interlayer insulating film 190 may be coplanar with the upper surface 145US of the gate capping pattern 145.

The first interlayer insulating film 190 is disposed on the first surface 50_S1 of the first back wiring line 50 and the first surface 60_S1 of the second back wiring line 60. The first interlayer insulating film 190 may be disposed on the first source/drain pattern 150 and the second source/drain pattern 160. The first interlayer insulating film 190 may not cover the upper surface of the gate capping pattern 145. For example, the upper surface of the first interlayer insulating film 190 may be coplanar with the upper surface 145US of the gate capping pattern 145.

The first interlayer insulating film 190 may include, for example, at least one of silicon oxide, silicon nitride, silicon oxynitride, and a low dielectric constant material. The low dielectric constant material may include, for example, but is not limited to, at least one of Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SILK, Amorphous Fluorinated Carbon, silica aerogels, silica xerogels, mesoporous silica or combinations thereof.

The source/drain etching stop film may extend along a profile of the first source/drain pattern 150 and a profile of the second source/drain pattern 160. The source/drain etching stop film may be disposed between the first source/drain pattern 150 and the first interlayer insulating film 190, and between the second source/drain pattern 160 and the first interlayer insulating film 190. The source/drain etch stop film may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), and combinations thereof.

The first front source/drain contact 170F and the third front source/drain contact 175F may be disposed on the first lower pattern BP1. The first front source/drain contact 170F and the third front source/drain contact 175F may be connected to the source/drain patterns 150 and 160 disposed on the first lower pattern BP1.

The second front source/drain contact 270F and the fourth front source/drain contact 275F may be disposed on the second lower pattern BP2. The second front source/drain contact 270F and the fourth front source/drain contact 275F may be connected to the source/drain pattern disposed on the second lower pattern BP2.

The first front source/drain contact 170F may be connected to the first source/drain pattern 150. The first front source/drain contact 170F is electrically connected to the first source/drain pattern 150.

The first front source/drain contact 170F may be disposed inside the first interlayer insulating film 190 and the first source/drain pattern 150. A portion of the first front source/drain contact 170F may be disposed inside the first source/drain pattern 150.

The first front source/drain contact 170F may include a first surface 170F_S1 and a second surface 170F_S2 that are opposite to each other in the third direction Z. The first front source/drain contact 170F may include side walls 170F_SW extending in the third direction Z.

The second surface 170F_S2 of the first front source/drain contact 170F may face the first back wiring line 50 and the second back wiring line 60. The first surface 170F_S1 of the first front source/drain contact 170F may be the upper surface of the first front source/drain contact 170F. The second surface 170F_S2 of the first front source/drain contact 170F may be a bottom surface of the first front source/drain contact 170F.

For example, a height from the first surface 50_S1 of the first back wiring line 50 to the second surface 170F_S2 of the first front source/drain contact 170F may be the same as or smaller than a height from the first surface 50_S1 of the first back wiring line 50 to the first surface BP1_S1 of the first lower pattern BP1.

The third front source/drain contact 175F may be connected to the second source/drain pattern 160. The third front source/drain contact 175F is electrically connected to the second source/drain pattern 160.

The third front source/drain contact 175F may be disposed inside the first interlayer insulating film 190 and the second source/drain pattern 160. A portion of the third front source/drain contact 175F may be disposed inside the second source/drain pattern 160.

The third front source/drain contact 175F may include a first surface 175F_S1 and a second surface 175F_S2 that are opposite to each other in the third direction Z. The third front source/drain contact 175F may include side walls 175F_SW extending in the third direction Z.

The second surface 175F_S2 of the third front source/drain contact 175F may face the first back wiring line 50 and the second back wiring line 60. The first surface 175F_S1 of the third front source/drain contact 175F may be the upper surface of the third front source/drain contact 175F. The second surface 175F_S2 of the third front source/drain contact 175F may be a bottom surface of the third front source/drain contact 175F.

For example, a height from the first surface 50_S1 of the first back wiring line 50 to the second surface 175F_S2 of the third front source/drain contact 175F may be the same as or smaller than a height from the first surface 50_S1 of the first back wiring line 50 to the first surface BP1_S1 of the first lower pattern BP1.

The first front source/drain contact 170F and the third front source/drain contact 175F may contact the gate spacer 140. The side walls 170F_SW of the first front source/drain contact 170F and the side walls 175F_SW of the third front source/drain contact 175F may contact the gate spacer 140.

The height from the upper surface AP1_US of the first active pattern AP1 to the first surface 170F_S1 of the first front source/drain contact 170F may be the same as the height from the upper surface AP1_US of the first active pattern AP1 to the upper surface 145US of the gate capping pattern 145. The height from the upper surface AP1_US of the first active pattern AP1 to the first surface 175F_S1 of the third front source/drain contact 175F may be the same as the height from the upper surface AP1_US of the first active pattern AP1 to the upper surface 145US of the gate capping pattern 145.

The second front source/drain contact 270F and the fourth front source/drain contact 275F may be substantially the same as the first front source/drain contact 170F and the third front source/drain contact 175F, and repeated descriptions may be omitted.

A first contact silicide film 155 may be disposed between the first front source/drain contact 170F and the first source/drain pattern 150. The first contact silicide film 155 may contact the first front source/drain contacts 170F.

The first contact silicide film 155 may extend along the side walls 170F_SW of the first front source/drain contact 170F. The first contact silicide film 155 may cover a portion of the side walls 170F_SW of the first front source/drain contact 170F. The first contact silicide film 155 may not extend along the second surface 170F_S2 of the first front source/drain contact 170F. The second surface 170F_S2 of the first front source/drain contact 170F and the side wall 170F_SW of the first front source/drain contact 170F may be distinguished depending on the presence or absence of contact of the first contact silicide film 155.

A second contact silicide film 165 may be disposed between the third front source/drain contact 175F and the second source/drain pattern 160. The second contact silicide film 165 may contact the third front source/drain contact 175F.

The second contact silicide film 165 may extend along side walls 175F_SW of the third front source/drain contact 175F. The second contact silicide film 165 may cover a portion of the side walls 175F_SW of the third front source/drain contact 175F. The second contact silicide film 165 does not extend along the second surface 175F_S2 of the third front source/drain contact 175F. The second surface 175F_S2 of the third front source/drain contact 175F and the side wall 175F_SW of the third front source/drain contact 175F may be distinguished depending on the presence or absence of contact of the second contact silicide film 165.

A first defective semiconductor region 150DR may be disposed on the second surface 170F_S2 of the first front source/drain contact 170F. The first defective semiconductor region 150DR may contact the second surface 170F_S2 of the first front source/drain contact 170F. The first defective semiconductor region 150DR may not extend along the side walls 170F_SW of the first front source/drain contact 170F.

A second defective semiconductor region 160DR may be disposed on the second surface 175F_S2 of the third front source/drain contact 175F. The second defective semiconductor region 160DR may contact the second surface 175F_S2 of the third front source/drain contact 175F. The second defective semiconductor region 160DR may not extend along the side walls 175F_SW of the third front source/drain contact 175F.

In the cross-sectional views such as FIGS. 2, 4A and 4B, the second surface 175F_S2 of the third front source/drain contact 175F and the side wall 175F_SW of the third front source/drain contact 175F may be distinguished by the presence or absence of contact of the second defective semiconductor region 160DR.

The first defective semiconductor region 150DR may include the same semiconductor material as the first source/drain pattern 150. The second defective semiconductor region 160DR may include the same semiconductor material as the second source/drain pattern 160. Since the first source/drain pattern 150 and the second source/drain pattern 160 are formed by an epitaxial growth method, the first source/drain pattern 150 and the second source/drain pattern 160 may have a crystal lattice structure. However, the first defective semiconductor region 150DR and the second defective semiconductor region 160DR may have a broken shape of the crystal lattice structure. For example, when the second source/drain pattern 160 and the second defective semiconductor region 160DR are analyzed using an analysis device such as a transmission electron microscopy (TEM), the second source/drain pattern 160 and the second defective semiconductor region 160DR may be distinguished through the shape in which the semiconductor material is arranged.

The first back source/drain contact 170B may be disposed between the first front source/drain contact 170F and the first back wiring line 50. The first back source/drain contact 170B may contact the first front source/drain contact 170F. For example, the first back source/drain contact 170B may be directly connected to the first front source/drain contact 170F.

The first back source/drain contact 170B may be connected to the first back wiring line 50. The first back source/drain contact 170B may be connected to the first surface 50_S1 of the first back wiring line 50.

The first back source/drain contact 170B may be disposed inside the first lower pattern BP1. The first back source/drain contact 170B may pass through the first lower pattern BP1 in the third direction Z, but is not limited thereto.

The first back source/drain contact 170B may include a first surface 170B_S1 and a second surface 170B_S2 that are opposite to each other in the third direction Z. The first back source/drain contact 170B may include side walls 170B_SW extending in the third direction Z. The second surface 170B_S2 of the first back source/drain contact 170B may be the bottom surface of the first back source/drain contact 170B. The first surface 170B_S1 of the first back source/drain contact 170B may be the upper surface of the first back source/drain contact 170B.

The second surface 170B_S2 of the first back source/drain contact 170B may face the first back wiring line 50. The second surface 170B_S2 of the first back source/drain contact 170B may be connected to the first back wiring line 50.

The first surface 170B_S1 of the first back source/drain contact 170B may face the first front source/drain contact 170F. The first surface 170B_S1 of the first back source/drain contact 170B may be directly connected to the second surface 170F_S2 of the first front source/drain contact 170F.

In the semiconductor device according to some embodiments, the width of the second surface 170F_S2 of the first front source/drain contact 170F in the first direction X may be greater than the width of the first surface 170B_S1 of the first back source/drain contact 170B in the first direction X.

The first back source/drain contact 170B passes through the first defective semiconductor region 150DR, and may be connected to the first front source/drain contact 170F. The first back source/drain contact 170B may contact the first defective semiconductor region 150DR. The side wall 170B_SW of the first back source/drain contact 170B may contact the first defective semiconductor region 150DR.

The second back source/drain contact 270B may be connected to the second back wiring line 60. The second back source/drain contact 270B may be directly connected to the second front source/drain contact 270F. The second back source/drain contact 270B may be substantially the same as the first back source/drain contact 170B, and repeated descriptions may be omitted.

For example, front source/drain contacts 170F, 175F, 270F, and 275F may each have a single film structure. The back source/drain contacts 170B and 270B may each have a single film structure. The front source/drain contacts 170F, 175F, 270F, and 275F and the back source/drain contacts 170B and 270B may not be multi-film structures including different materials from each other.

The front source/drain contacts 170F, 175F, 270F, and 275F and the back source/drain contacts 170B and 270B may be formed of one conductive material. The front source/drain contacts 170F, 175F, 270F, and 275F and the back source/drain contacts 170B and 270B may have a single conductive film structure. The front source/drain contacts 170F, 175F, 270F, and 275F and the back source/drain contacts 170B and 270B may include impurities that are introduced unintentionally in the process of forming the contact.

As an example, the front source/drain contacts 170F, 175F, 270F, and 275F may be formed of a single grain. As another example, the front source/drain contacts 170F, 175F, 270F, and 275F may include a plurality of grains divided by a grain boundary.

As an example, the back source/drain contacts 170B and 270B may be formed of a single grain. As another example, the back source/drain contacts 170B and 270B may include a plurality of grains divided by the grain boundary.

The front source/drain contacts 170F, 175F, 270F, and 275F and the back source/drain contacts 170B and 270B may include metals capable of selectively growing on the conductive materials. The front source/drain contacts 170F, 175F, 270F, and 275F and the back source/drain contacts 170B and 270B may include, for example, but are not limited to, one of titanium (Ti), tungsten (W), molybdenum (Mo), ruthenium (Ru), and cobalt (Co).

The first contact silicide film 155 and the second contact silicide film 165 may include a metal silicide material.

The contact insulating liner 171 may be disposed between the first lower pattern BP1 and the first back source/drain contact 170B. The contact insulating liner 171 may extend along side walls 170B_SW of the first back source/drain contact 170B.

For example, the contact insulating liner 171 may extend along a portion of the side wall 170B_SW of the first back source/drain contact 170B. The contact insulating liner 171 may not extend up to the first surface 170B_S1 of the first back source/drain contact 170B.

The contact insulating liner 171 may not extend up to the first front source/drain contact 170F. The contact insulating liner 171 may not contact the first front source/drain contact 170F.

For example, the contact insulating liner 171 may contact the first defective semiconductor region 150DR. Because the first defective semiconductor region 150DR contacts the second surface 170F_S2 of the first front source/drain contact 170F, the contact insulating liner 171 may not contact the first contact silicide film 155.

The contact insulating liner 171 may be made of an insulating material. The contact insulating liner 171 may include, but is not limited to, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a low dielectric constant material.

A contact insulating liner 171 may be disposed between the second lower pattern BP2 and the second back source/drain contact 270B.

Since the first front source/drain contact 170F is directly connected to the first back source/drain contact 170B, a high-resistance semiconductor pattern is not disposed between the first front source/drain contact 170F and the first back source/drain contacts 170B. Accordingly, the resistance between the first front source/drain contact 170F and the first back source/drain contact 170B may decrease.

The second interlayer insulating film 191 may be disposed on the first interlayer insulating film 190, the gate structure GS, and the front source/drain contacts 170F, 175F, 270F, and 275F. The second interlayer insulating film 191 may include, for example, at least one of silicon oxide, silicon nitride, silicon carbonitride, silicon oxynitride, and a low dielectric constant material.

The front wiring structure 195 may be disposed inside the second interlayer insulating film 191. The front wiring structure 195 is disposed on the first surface 50_S1 of the first back wiring line and the first surface 60_S1 of the second back wiring line 60. The front wiring structure 195 may include a front via plug 196 and a front wiring line 197.

The front wiring structure 195 may be connected to the first front source/drain contact 170F and the third front source/drain contact 175F. The front wiring structure 195 may be connected to the first surface 170F_S1 of the first front source/drain contact 170F and the first surface 175F_S1 of the third front source/drain contact 175F.

The first front source/drain contact 170F may be disposed between the front wiring line 197 and the first back source/drain contact 170B. The first front source/drain contact 170F may not be connected to the front wiring structure 195.

The front wiring structure 195 may be connected to the second front source/drain contact 270F and/or the fourth front source/drain contact 275F.

The front via plug 196 and the front wiring line 197 may each include at least one of, for example, metal, conductive metal nitride, conductive metal carbide, conductive metal oxide, conductive metal carbonitride, and a 2D material.

Although the front via plug 196 and the front wiring line 197 are each shown as being a single conductive film structure, this example is only for convenience of explanation and is not limited thereto. As an example, at least one of the front via plug 196 and the front wiring line 197 may have multiple conductive film structures. As another example, the front wiring structure 195 may have an integral structure with no boundary division between the front via plug 196 and the front wiring line 197.

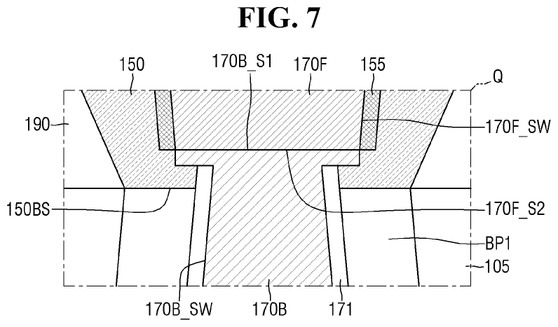

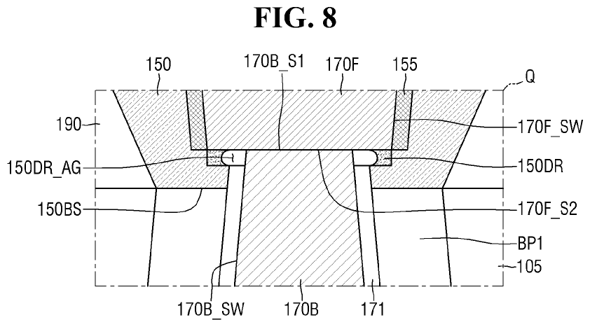

FIGS. 7 and 8 are diagrams illustrating a semiconductor device according to some embodiments. FIGS. 7 and 8 may include features similar to those described with respect to FIGS. 1 to 6, and repeated descriptions may be omitted. For reference, FIGS. 7 and 8 are enlarged views of a portion Q of FIG. 4A.

Referring to FIG. 7, in the semiconductor device according to some embodiments, a portion of the first back source/drain contact 170B may be interposed between the contact insulating liner 171 and the first front source/drain contact 170F.

The first back source/drain contact 170B may be disposed between the top of the contact insulating liner 171 and the second surface 170F_S2 of the first front source/drain contact. The first defective semiconductor region (150DR of FIG. 6) may not be disposed between the contact insulating liner 171 and the first front source/drain contact 170F.

Referring to FIG. 8, in the semiconductor device according to some embodiments, an epi-air gap 150DR_AG may be disposed between the first back source/drain contact 170B and the first defective semiconductor region 150DR.

The epi-air gap 150DR_AG may be disposed between the top of the insulating liner 171 and the second surface 170F_S2 of the first front source/drain contact. The side walls 170B_SW of the first back source/drain contact 170B may contact the epi-air gap 150DR_AG.

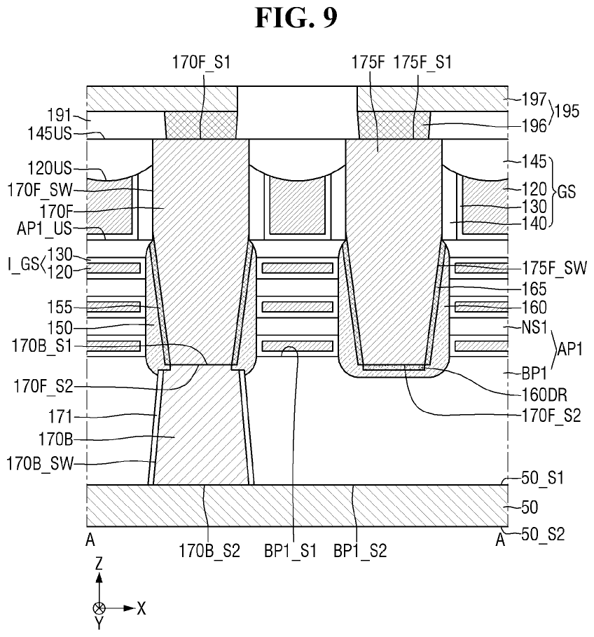

FIGS. 9 to 11 are diagrams illustrating a semiconductor device according to some embodiments. FIGS. 9 to 11 may include features similar to those described with respect to FIGS. 1 to 6, and repeated descriptions may be omitted.

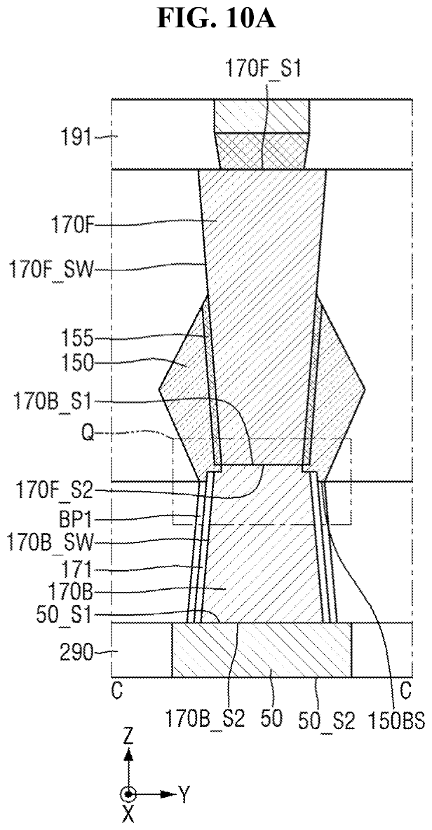

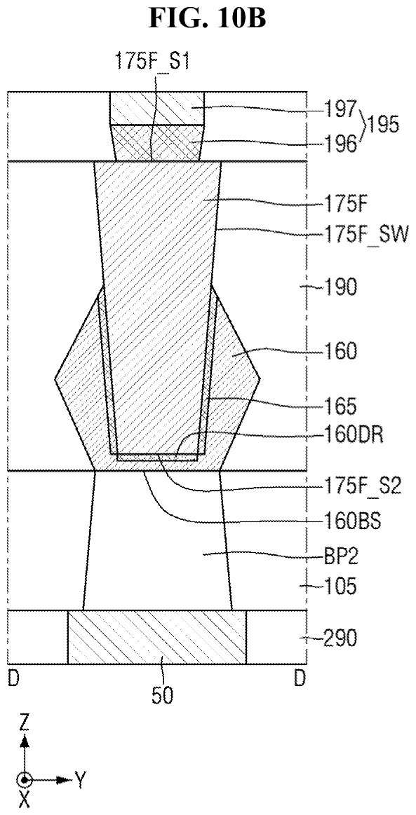

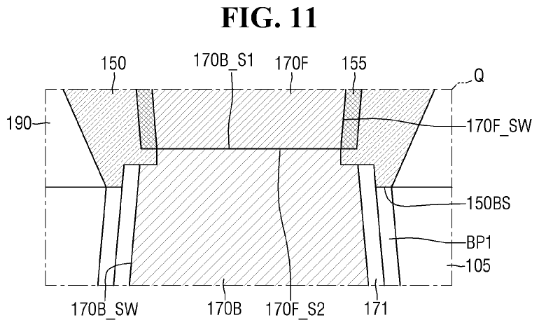

For reference, FIG. 9 is a cross-sectional view taken along line A-A of FIG. 1. FIGS. 10A and 10B are cross-sectional views taken along C-C and D-D of FIG. 1, respectively. FIG. 11 is an enlarged view of a portion Q of FIG. 10A.

Referring to FIGS. 9 to 11, in the semiconductor device according to some embodiments, the width of the second surface 170F_S2 of the first front source/drain contact 170F in the first direction X may be smaller than or equal to the width of the first surface 170B_S1 of the first back source/drain contact 170B in the first direction X.

No defective semiconductor region is disposed on the second surface 170F_S2 of the first front source/drain contact.

The first source/drain pattern 150 may contact the side walls 170B_SW of the first back source/drain contact 170B. A portion of the first source/drain pattern 150 may be interposed between the insulating liner 171 and the first contact silicide film 155.

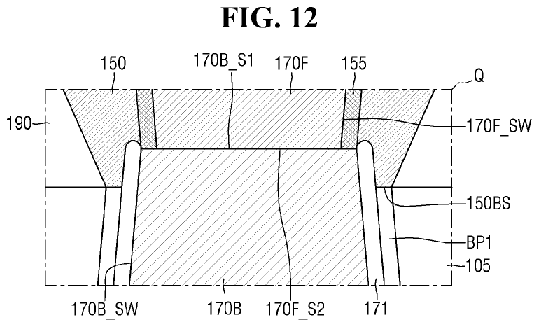

FIG. 12 is a diagram illustrating a semiconductor device according to some embodiments. FIG. 12 may include features similar to those described with respect to FIGS. 9 to 11, and repeated descriptions may be omitted.

For reference, FIG. 12 is an enlarged view of a portion Q of FIG. 10A.

Referring to FIG. 12, in the semiconductor device according to some embodiments, the first back source/drain contact 170B may contact the first front source/drain contact 170F and the first contact silicide film 155.

The contact insulating liner 171 may extend along the entire side wall 170B_SW of the first back source/drain contact 170B. The contact insulating liner 171 may protrude beyond the first surface 170B_S1 of the first back source/drain contact 170B in the third direction Z.

The contact insulating liner 171 may contact the first contact silicide film 155. The contact insulating liner 171 may not contact the second surface 170F_S2 of the first front source/drain contact 170F.

FIGS. 13 and 14 are diagrams illustrating a semiconductor device according to some embodiments. FIGS. 13 and 14 may include features similar to those described with respect to FIGS. 1 to 6, and repeated descriptions may be omitted.

Referring to FIGS. 13 and 14, in the semiconductor device according to some embodiments, the first front source/drain contact 170F, the third front source/drain contact 175F and the first back source/drain contact 170B may have a multi-conductive film structure.

The first front source/drain contacts 170F may include a first front contact barrier film 170Fa and a first front contact plug film 170Fb. The third front source/drain contact 175F may include a second front contact barrier film 175Fa and a second front contact plug film 175Fb. The first back source/drain contact 170B may include a back contact barrier film 170Ba and a back contact plug film 170Bb.

In FIG. 13, the first front contact barrier film 170Fa and the back contact barrier film 170Ba may be disposed between the first front contact plug film 170Fb and the back contact plug film 170Bb. The first front contact plug film 170Fb may not be directly connected to the first back source/drain contact 170B.

In FIG. 14, the back contact barrier film 170Ba may be disposed between the first front contact plug film 170Fb and the back contact plug film 170Bb. The first front contact barrier film 170Fa may not be disposed between the first front contact plug film 170Fb and the back contact plug film 170Bb. The first front contact plug film 170Fb may be directly connected to the first back source/drain contact 170B.

The first front contact barrier film 170Fa, the second front contact barrier film 175Fa, and the back contact barrier film 170Ba may each include at least one of metal, conductive metal nitride, conductive metal carbide, conductive metal oxide, conductive metal carbonitride, and a 2D material. The first front contact plug film 170Fb, the second front contact plug film 175Fb, and the back contact plug film 170Bb may each include metal.

As an example, the first front source/drain contact 170F and the third front source/drain contact 175F have a multiple conductive film structure, and the first back source/drain contact 170B may have a single conductive film structure. As another example, the first front source/drain contact 170F and the third front source/drain contact 175F may have a single conductive layer structure, and the first back source/drain contact 170B may have a multiple conductive layer structure.

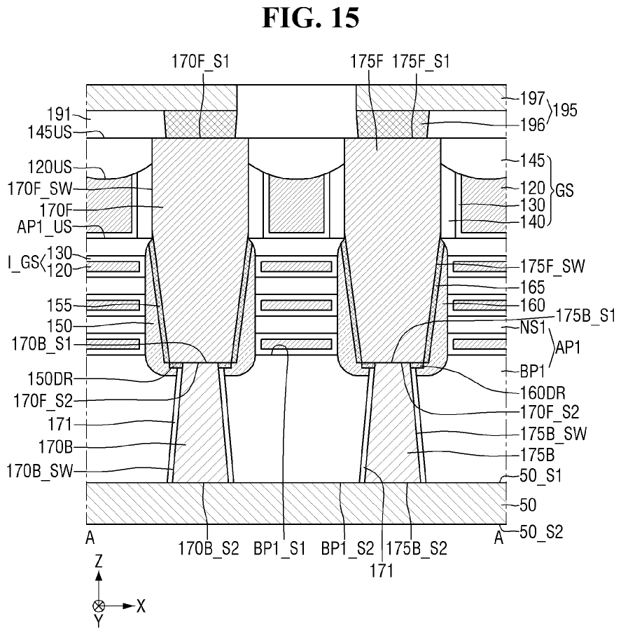

FIG. 15 is a diagram illustrating a semiconductor device according to some embodiments. FIG. 15 may include features similar to those described with respect to FIGS. 1 to 6, and repeated descriptions may be omitted.

Referring to FIG. 15, the semiconductor device according to some embodiments may further include a third back source/drain contact 175B disposed between the third front source/drain contact 175F and the first back wiring line 50.

The third back source/drain contact 175B may contact the third front source/drain contact 175F. For example, the third back source/drain contact 175B may be directly connected to the third front source/drain contact 175F.

The third back source/drain contact 175B may be connected to the first back wiring line 50. The third back source/drain contact 175B may be connected to the first surface 50_S1 of the first back wiring line 50.

The third back source/drain contact 175B may be disposed inside the first lower pattern BP1. The third back source/drain contact 175B may pass through the first lower pattern BP1 in the third direction Z, but is not limited thereto.

When the first back wiring line 50 and the second back wiring line 60 extend in the second direction Y, the third back source/drain contact 175B may be connected to the second back wiring line 60.

The third back source/drain contact 175B may include a first surface 175B_S1 and a second surface 175B_S2 that are opposite to each other in the third direction Z. The third back source/drain contact 175B may include side walls 175B_SW extending in the third direction Z.

The second surface 175B_S2 of the third back source/drain contact 175B may face the first back wiring line 50. The second surface 175B_S2 of the third back source/drain contact 175B may be connected to the first back wiring line 50.

The first surface 175B_S1 of the third back source/drain contact 175B may be surface the third front source/drain contact 175F. The first surface 175B_S1 of the third back source/drain contact 175B may be directly connected to the second surface 175F_S2 of the third front source/drain contact 175F.

The contact insulating liner 171 may be disposed between the first lower pattern BP1 and the third back source/drain contact 175B. The contact insulating liner 171 may extend along the side walls 175B_SW of the third back source/drain contact 175B.

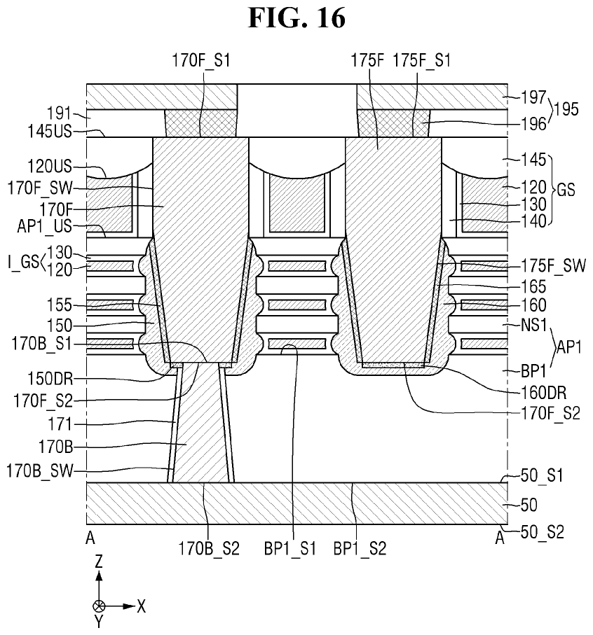

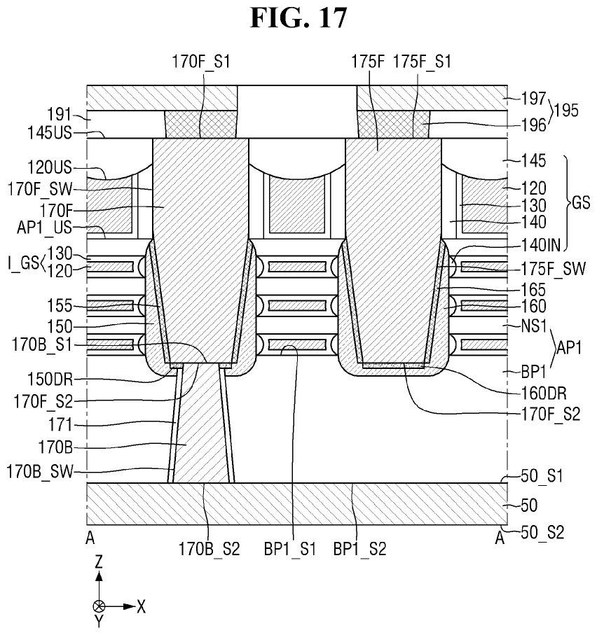

FIGS. 16 and 17 are diagrams illustrating a semiconductor device according to some embodiments, respectively. FIGS. 16 and 17 may include features similar to those described with respect to FIGS. 1 to 6, and repeated descriptions may be omitted.

Referring to FIG. 16, in the semiconductor device according to some embodiments, the first source/drain pattern 150 and the second source/drain pattern 160 may include respective outer side walls that abuts on the first sheet pattern NS1 and the inner gate structure I_GS1.

The outer side wall of the first source/drain pattern 150 and the outer side wall of the second source/drain pattern 160 may have a wave-like shape.

Referring to FIG. 17, in the semiconductor device according to some embodiments, the gate structure GS may further include a plurality of inner spacers 140IN.

The inner spacer 140IN may be disposed between the first sheet patterns NS1 adjacent in the third direction Z, and between the first lower pattern BP1 and the first sheet pattern NS1. The inner spacer 140IN may be disposed between the inner gate structure I_GS and the first source/drain pattern 150. The inner spacer 140IN may be disposed between the inner gate structure I_GS and the second source/drain pattern 160.

The inner gate structure I_GS may not contact the first source/drain pattern 150. The inner gate structure I_GS may not contact the second source/drain pattern 160.

For example, the first source/drain pattern 150 and the second source/drain pattern 160 may include n-type dopants.

FIGS. 18 to 20B are diagrams illustrating a semiconductor device according to some embodiments. FIGS. 18 to 20B may include features similar to those described with respect to FIGS. 1 to 6, and repeated descriptions may be omitted.

Referring to FIGS. 18 to 20B, the semiconductor device according to some embodiments may further include a substrate 100 disposed between the first back wiring line 50 and the first lower pattern BP1, and between the second back wiring line 60 and the second lower pattern BP2.

The substrate 100 may include an upper surface 100US and a lower surface 100BS that are opposite to each other in the third direction Z. The substrate 100 may be a bulk silicon or a silicon-on-insulator (SOI). In contrast, the substrate 100 may be a silicon substrate, or may include, but not limited to, silicon germanium, silicon germanium on insulator (SGOI), indium antimonide, lead tellurium compounds, indium arsenic, indium phosphide, gallium arsenide or gallium antimonide.

The first active pattern AP1 and the second active pattern AP2 may be disposed on the upper surface 100US of the substrate. The first lower pattern BP1 and the second lower pattern BP2 may each protrude from the upper surface 100US of the substrate in the third direction Z. The field insulating film 105 may be disposed on the upper surface 100US of the substrate 100.

The first back wiring line 50 and the second back wiring line 60 may be disposed on the lower surface 100BS of the substrate 100.

The first back source/drain contact 170B may be disposed in the first lower pattern BP1 and the substrate 100. The first back source/drain contact 170B may pass through the substrate 100 in the third direction Z.

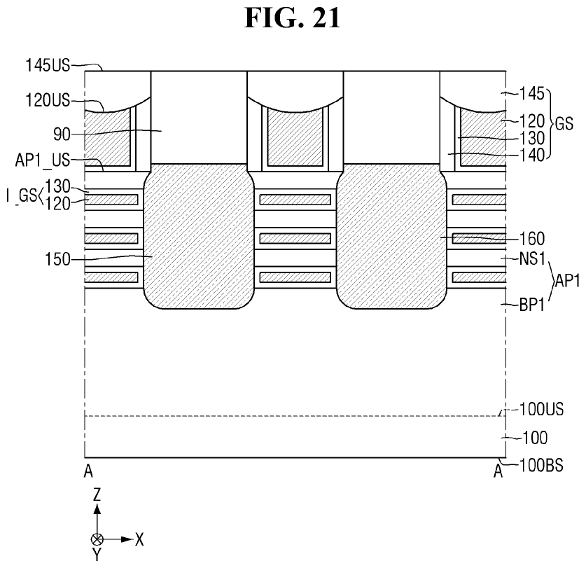

FIGS. 21 to 29 are diagrams illustrating a method for fabricating a semiconductor device according to some embodiments. For reference, FIGS. 21 to 29 may be an example method for fabricating the semiconductor device described above.

Referring to FIG. 21, the first source/drain pattern 150 and the second source/drain pattern 160 may be formed on the first lower pattern BP1.

The gate spacer 140 may be formed on the first lower pattern BP1 before the first source/drain pattern 150 and the second source/drain pattern 160 are formed.

The first interlayer insulating film 190 may be formed on the first source/drain pattern 150 and the second source/drain pattern 160. Subsequently, the first sheet pattern NS1 may be formed on the first lower pattern BP1. The first active pattern AP1 may be formed on the upper surface 100US of the substrate, accordingly.

Subsequently, the gate insulating film 130 and the gate electrode 120 that surround or at least partially surround the first sheet pattern NS1 may be formed on the first lower pattern BP1. The gate capping pattern 145 may be formed on the gate electrode 120. The gate structure GS may be formed on the first active pattern AP1, accordingly. The upper surface 145US of the gate capping pattern 145 may be coplanar with an upper surface of the first interlayer insulating film 190.

A source/drain etching stop film may be further formed between the first interlayer insulating film 190 and the first source/drain patterns 150, and between the first interlayer insulating film 190 and the second source/drain pattern 160.

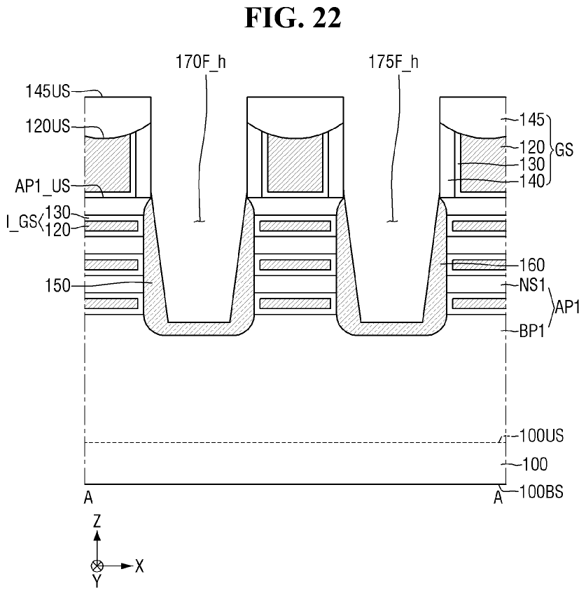

Referring to FIGS. 21 and 22, a first front contact hole 170F_h and a second front contact hole 175F_h may be formed on the substrate 100.

The first front contact hole 170F_h may be formed in the first interlayer insulating film 190 and the first source/drain pattern 150. The second front contact hole 175F_h may be formed in the first interlayer insulating film 190 and the second source/drain pattern 160.

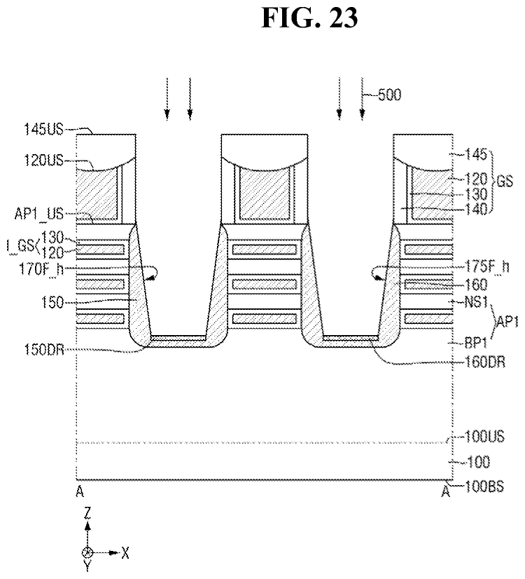

Referring to FIG. 23, the first defective semiconductor region 150DR may be formed in the first front contact hole 170F_h, using a surface treatment process 500. The second defective semiconductor region 160DR may be formed in the second front contact holes 175F_h, using the surface treatment process 500.

The first defective semiconductor region 150DR may be formed on the bottom surface of the first front contact hole 170F_h. The first defective semiconductor region 150DR may be formed by breakage of the semiconductor crystal structure in a portion of the first source/drain pattern 150.

The second defective semiconductor region 160DR may be formed on the bottom surface of the second front contact hole 175F_h. The first defective semiconductor region 150DR may be formed by breakage of the semiconductor crystal structure in a portion of the first source/drain pattern 150.

The surface treatment process 500 may be an ion bombardment process that causes directional ions to collide with the source/drain patterns 150 and 160.

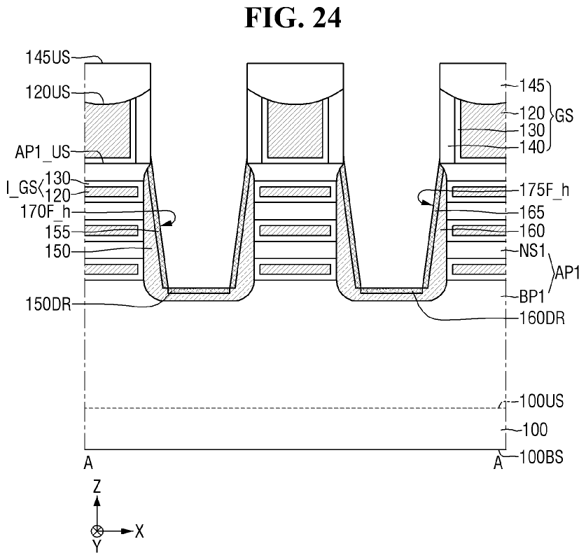

Although the first defective semiconductor region 150DR is shown as not being formed on the side wall of the first front contact hole 170F_h, the example is only for convenience of explanation and is not limited thereto. When the first defective semiconductor region 150DR is formed on the side wall of the first front contact hole 170F_h, the thickness of the first defective semiconductor region 150DR formed on the side wall of the first front contact hole 170F_h may be smaller than the thickness of the first defective semiconductor region 150DR formed on the bottom surface of the first front contact hole 170F_h. The thickness of the first defective semiconductor region 150DR formed on the side wall of the first front contact hole 170F_h may not disturb formation of the contact silicide films 155 and 165 of FIG. 24.

Referring to FIG. 24, the first contact silicide film 155 may be formed on the side walls of the first front contact hole 170F_h.

The first contact silicide film 155 may be formed on the first source/drain pattern 150 exposed by the first front contact hole 170F_h. The first contact silicide film 155 is not formed on the bottom surface of the first front contact hole 170F_h. The first defective semiconductor region 150DR formed on the bottom surface of the first front contact hole 170F_h may prevent the first contact silicide film 155 from being formed.

The second contact silicide film 165 may be formed on the side walls of the second front contact hole 175F_h. The second contact silicide film 165 may be formed on the second source/drain pattern 160 exposed by the second front contact hole 175F_h. The second contact silicide film 165 is not formed on the bottom surface of the second front contact hole 175F_h. The second defective semiconductor region 160DR formed on the bottom surface of the second front contact hole 175F_h may prevent the second contact silicide film 165 from being formed.

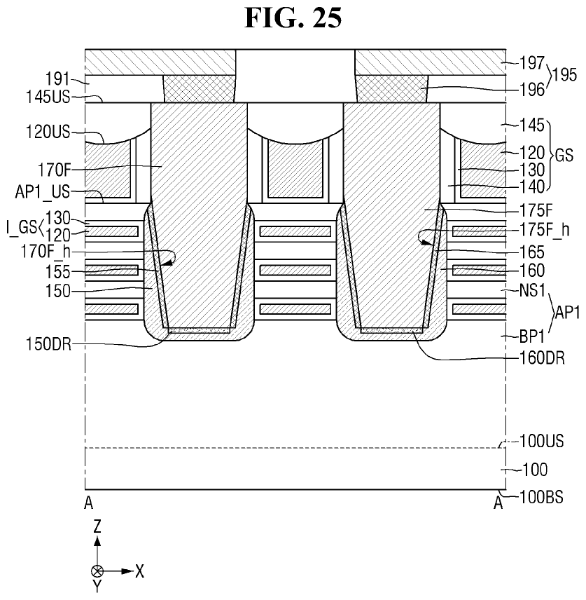

Referring to FIG. 25, the first front source/drain contact 170F may be formed on the first contact silicide film 155.

The first front source/drain contact 170F may be formed inside the first front contact hole 170F_h. The first front source/drain contact 170F may be connected to the first source/drain pattern 150.

A third front source/drain contact 175F may be formed on the second contact silicide film 165. The third front source/drain contact 175F may be formed inside the second front contact hole 175F_h. The third front source/drain contact 175F may be connected to the second source/drain pattern 160.

A front wiring structure 195 may then be formed on the gate structure GS. The front wiring structure 195 may be connected to the first front source/drain contact 170F and the third front source/drain contact 175F.

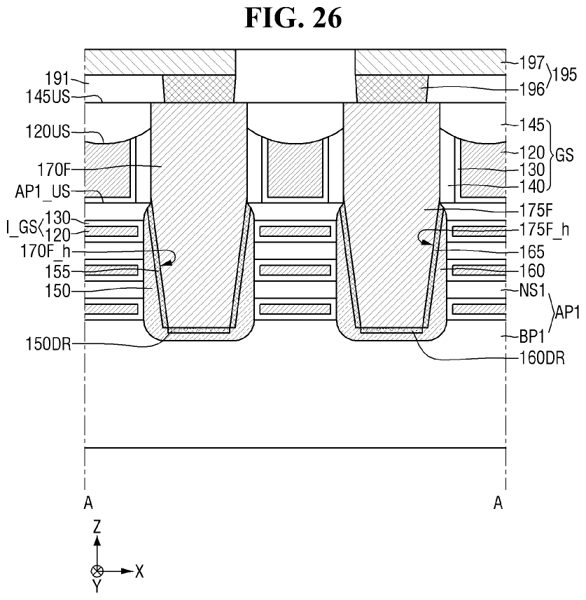

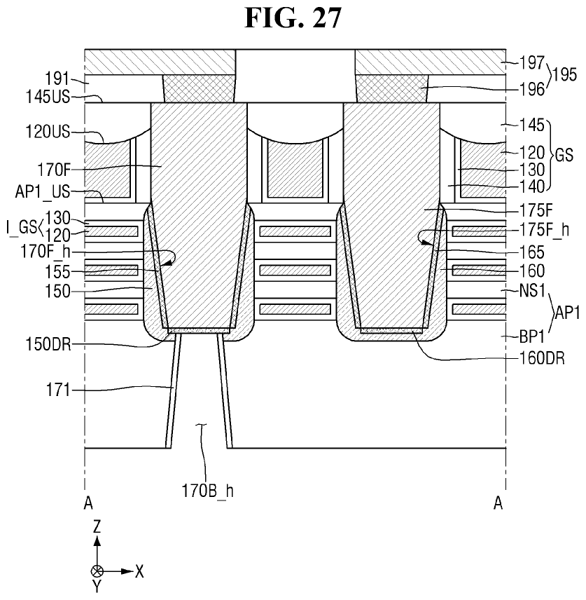

Referring to FIGS. 26 and 27, after forming the front wiring structure 195, the substrate 100 may be removed.

A portion of the substrate 100 may be removed to reduce the thickness of the substrate 100.

A back contact hole 170B_h may then be formed inside the first lower pattern BP1. The back contact hole 170B_h may expose the first defective semiconductor region 150DR.

A contact insulating liner 171 may then be formed along the side walls of the back contact holes 170B_h. The contact insulating liner 171 may contact the first defective semiconductor region 150DR.

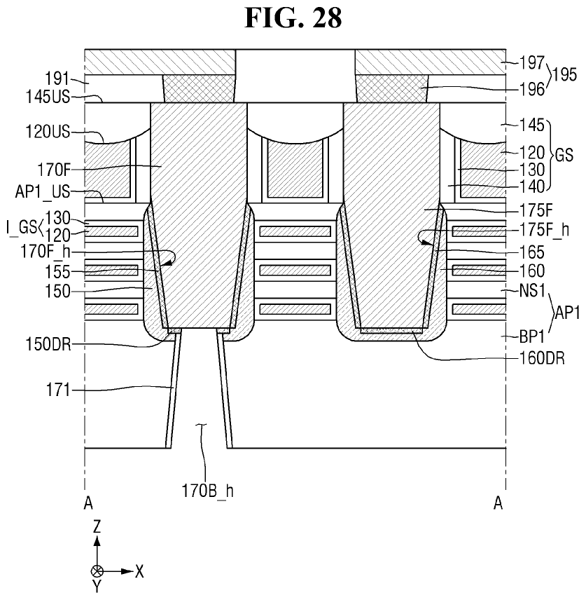

Referring to FIGS. 27 and 28, at least a portion of the first defective semiconductor region 150DR exposed by the back contact hole 170B_h may be removed.

The first defective semiconductor region 150DR may be removed to expose the first front source/drain contact 170F.

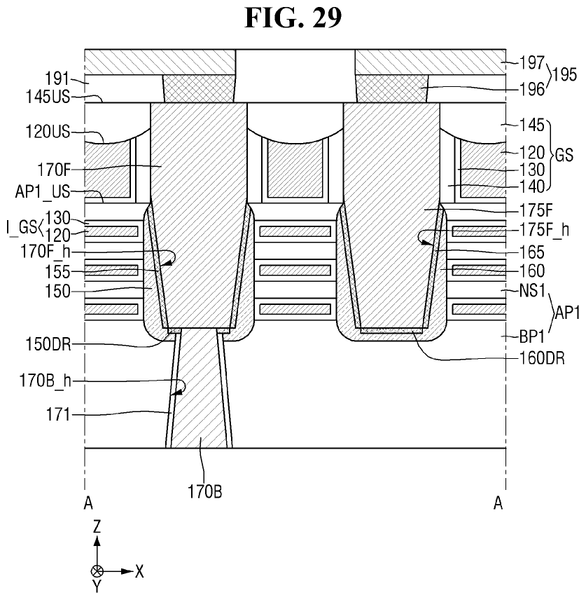

Referring to FIG. 29, the first back source/drain contact 170B may be formed inside the back contact hole 170B_h.

The first back source/drain contact 170B may be directly connected to the first front source/drain contact 170F.

Next, referring to FIG. 2, the first back wiring line 50 and the second back wiring line 60 may be formed. The first back wiring line 50 may be connected to the first back source/drain contact 170B.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a back interlayer insulating film;
a back wiring line in the back interlayer insulating film, the back wiring line comprising a first surface and a second surface opposite the first surface in a first direction;
a fin-type pattern on the first surface of the back wiring line and extending in a second direction;
a gate electrode on the fin-type pattern and extending in a third direction;
a first source/drain pattern on a first side of the gate electrode, the first source/drain pattern comprising a bottom surface contacting the fin-type pattern;
a back source/drain contact in the fin-type pattern and connected to the first surface of the back wiring line;
a contact insulating liner between the fin-type pattern and the back source/drain contact, the contact insulating liner extending along at least a portion of side walls of the back source/drain contact;
a first front source/drain contact directly connected to the back source/drain contact; and
a first contact silicide film between the first front source/drain contact and the first source/drain pattern.

2. The semiconductor device of claim 1, wherein the back source/drain contact comprises:
a first surface connected to the back wiring line; and
a second surface opposite to the first surface of the back source/drain contact in the first direction, and
wherein the contact insulating liner does not extend to the second surface of the back source/drain contact.

3. The semiconductor device of claim 1, wherein the first contact silicide film does not extend along a bottom surface of the first front source/drain contact.

4. The semiconductor device of claim 1, further comprising:
a second source/drain pattern on the fin-type pattern on a second side of the gate electrode;
a second front source/drain contact connected to the second source/drain pattern; and
a second contact silicide film extending along side walls of the second front source/drain contact, and
wherein the second contact silicide film does not extend along a bottom surface of the second front source/drain contact.

5. The semiconductor device of claim 4, further comprising:
a defective semiconductor region contacting the second front source/drain contact, and extending along the bottom surface of the second front source/drain contact.

6. The semiconductor device of claim 1, further comprising:
a defective semiconductor region contacting a bottom surface of the first front source/drain contact.

7. The semiconductor device of claim 6, wherein the defective semiconductor region contacts the contact insulating liner.

8. The semiconductor device of claim 1, wherein the first front source/drain contact comprises a front contact barrier film and a front contact plug film.

9. The semiconductor device of claim 8, wherein the front contact plug film is directly connected to the back source/drain contact.

10. The semiconductor device of claim 1, further comprising a front wiring line on the gate electrode and connected to the first front source/drain contact,
wherein the first front source/drain contact is between the front wiring line and the back source/drain contact.

11. The semiconductor device of claim 1, further comprising a plurality of sheet patterns on the fin-type pattern and spaced apart from the fin-type pattern in the first direction,
wherein the first source/drain pattern contacts the plurality of sheet patterns.

12. The semiconductor device of claim 1, further comprising a substrate between the back wiring line and the fin-type pattern,
wherein the fin-type pattern protrudes from the substrate in the first direction, and
wherein the back source/drain contact penetrates the substrate.

13. A semiconductor device comprising:
a back interlayer insulating film;
a back wiring line in the back interlayer insulating film, and the back wiring line comprising a first surface and a second surface opposite the first surface in a first direction;
a fin-type pattern on the first surface of the back wiring line, and extending in a second direction;
a first source/drain pattern and a second source/drain pattern on the fin-type pattern and spaced apart in the second direction;
a gate electrode between the first source/drain pattern and the second source/drain pattern;
a back source/drain contact in the fin-type pattern and connected to the first surface of the back wiring line;
a first front source/drain contact directly connected to the back source/drain contact, the first front source/drain contact comprising at least a portion in the first source/drain pattern;
a second front source/drain contact connected to the second source/drain pattern, the second front source/drain contact comprising at least a portion in the second source/drain pattern;
a first contact silicide film between the first front source/drain contact and the first source/drain pattern; and
a second contact silicide film extending along side walls of the second front source/drain contact,
wherein the second contact silicide film does not extend along a bottom surface of the second front source/drain contact.

14. The semiconductor device of claim 13, further comprising:
a defective semiconductor region contacting the second front source/drain contact, and extending along the bottom surface of the second front source/drain contact.

15. The semiconductor device of claim 13, further comprising:
a defective semiconductor region contacting a bottom surface of the first front source/drain contact.

16. The semiconductor device of claim 13, further comprising a contact insulating liner between the fin-type pattern and the back source/drain contact, the contact insulating liner extending along side walls of the back source/drain contact,
wherein the contact insulating liner does not contact the first front source/drain contact.

17. The semiconductor device of claim 16, wherein the first contact silicide film does not extend along a bottom surface of the first front source/drain contact.

18. The semiconductor device of claim 13, further comprising a plurality of sheet patterns on the fin-type pattern, and spaced apart from the fin-type pattern in the first direction,
wherein the plurality of sheet patterns are disposed the first source/drain pattern and the second source/drain pattern.

19. A semiconductor device comprising:
a back interlayer insulating film;
a back wiring line in the back interlayer insulating film, the back wiring line comprising a first surface and a second surface opposite the first surface in a first direction;
a fin-type pattern on the first surface of the back wiring line, and extending in a second direction;
a plurality of sheet patterns on the fin-type pattern, and spaced apart from the fin-type pattern in the first direction;
a gate electrode on the fin-type pattern, extending in a third direction, and at least partially surrounding the plurality of sheet patterns;
a source/drain pattern on a side surface of the gate electrode, the source/drain pattern comprising a bottom surface contacting the fin-type pattern;
a back source/drain contact in the fin-type pattern and connected to the first surface of the back wiring line;
a contact insulating liner between the fin-type pattern and the back source/drain contact, the contact insulating liner extending along at least a portion of a side wall of the back source/drain contact;
a front source/drain contact directly connected to the back source/drain contact, the front source/drain contact comprising a least a portion in the source/drain pattern; and
a contact silicide film extending along a side wall of the front source/drain contact,
wherein the contact silicide film does not extend along a bottom surface of the front source/drain contact.

20. The semiconductor device of claim 19, wherein the contact insulating liner does not contact the front source/drain contact.
